(19) United States
(12) Patent Application Publication
(10) Pub. No.: US 2026/0136703 A1
(43) Pub. Date: May 14, 2026

(54) ELECTRONICAL DEVICE

(71) Applicant: STMicroelectronics International N.V., Geneva (CH)

(72) Inventors: Raul Andres BIANCHI, Myans (FR); Sebastien PLACE, Vaulnaveys le bas (FR); Christel Marie-Noëlle BUJ, Grenoble (FR); Dominique GOLANSKI, Gières (FR); Isobel NICHOLSON, Edinburgh (GB)

(73) Assignee: STMicroelectronics International N.V., Geneva (CH)

(21) Appl. No.: 19/370,415

(22) Filed: Oct. 27, 2025

(30) Foreign Application Priority Data
Nov. 8, 2024 (FR) FR2412224

(51) Int. Cl. H10F 77/20; H10F 30/225; H10F 71/00; H10F 77/30

(52) U.S. Cl. CPC H10F 77/206; H10F 30/225; H10F 71/134; H10F 77/306

(57) ABSTRACT

An electronical device comprising a single photon avalanche diode, the single photon avalanche diode comprising a PN junction, the PN junction having a first dimension smaller than 1.2 μm, the single photon avalanche diode being surrounded by an insulating wall, the first dimension being the smallest dimension of the junction.

### BACKGROUND

### Technical Field

The present disclosure relates generally to electronical devices and especially electronical devices comprising single photon avalanche diodes and their manufacturing method.

### Description of the Related Art

A single-photon avalanche diode (SPAD) is a solid-state photodetector within the same family as photodiodes and avalanche photodiodes (APDs), while also being fundamentally linked with basic diode behaviors. As with photodiodes and APDs, a SPAD is based around a semiconductor PN junction that can be illuminated with ionizing radiation. The fundamental difference between SPADs and APDs or photodiodes, is that a SPAD is biased well above its reverse-bias breakdown voltage and has a structure that allows operation without damage or undue noise.

### BRIEF SUMMARY

One embodiment provides an electronical device comprising a single photon avalanche diode, the single photon avalanche diode comprising a PN junction, the PN junction having a first dimension smaller than 1.2 μm, the single photon avalanche diode being surrounded by an insulating wall, the first dimension being the smallest dimension of the junction.

Another embodiment provides a manufacturing method for an electronical device comprising a single photon avalanche diode, the single photon avalanche diode comprising a PN junction, the method comprising a doping step for manufacturing at least part of the anode of the single photon avalanche diode, the PN junction having a first dimension smaller than 1.2 μm, the single photon avalanche diode being surrounded by an insulating wall, the first dimension being the smallest dimension of the junction.

According to an embodiment, the insulating wall comprises a conductive core and an insulating sheath.

According to an embodiment, the cathode of the single photon avalanche diode comprises an N-doped region located in a substrate, the anode of the single photon avalanche diode comprising a first part located in regard to the cathode, and a second part surrounding a region of the substrate, said region of the substrate being separated from the cathode by the first part.

According to an embodiment, the PN junction is formed by the first part of the anode, the cathode and the portion of the substrate located between the first part of the anode and the cathode.

According to an embodiment, a second dimension is lower than 0.5 μm, the second dimension being the smallest dimension of the overlap between the first part and the second part.

According to an embodiment, the first dimension is under 150%, for example under 130%, of the lateral spatial resolution of the doping method used to form at least part of the anode of the single photon avalanche diode.

According to an embodiment, the doping method used is ion implantation of dopant elements.

According to an embodiment, the first dimension is over 90% of the lateral spatial resolution of the doping method.

According to an embodiment, the lateral spatial resolution of a doping method is, when doping a region having the shape of a rectangular parallelepiped, the smallest value of the smallest dimension of the upper face of the region allowing the upper face of the region to be plane.

According to an embodiment, the first dimension is under 1 μm.

According to an embodiment, the first dimension is between 0.7 μm and 1.2 μm.

According to an embodiment, the device comprises a time of flight device, the single photon avalanche diode being part of the time of flight device.

According to an embodiment, the method comprises the formation of a hard mask, the hard mask comprising an opening, at least one of the dimensions of the opening being smaller than 150% of the lateral spatial resolution of the doping method.

According to an embodiment, the doping is made from the face closest to the cathode.

### BRIEF DESCRIPTION OF THE SEVERAL VIEWS OF THE DRAWINGS

The foregoing features and advantages, as well as others, will be described in detail in the following description of specific embodiments given by way of illustration and not limitation with reference to the drawings, in which:

FIGS. 1A and 1B illustrate the definition of the doping lateral spatial resolution;

FIG. 2 illustrates an embodiment of an electronical device comprising a single photon avalanche diode; and

FIGS. 3A-3E illustrate an example of breakdown probabilities in different single photon avalanche diodes.

FIG. 4 illustrates another embodiment of an electronic device comprising a single photon avalanche diode.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front,” “back,” “top,” “bottom,” “left,” “right,” etc., or to relative positional qualifiers, such as the terms “above,” “below,” “higher,” “lower,” etc., or to qualifiers of orientation, such as “horizontal,” “vertical,” etc., reference is made to the orientation shown in the figures.

Unless specified otherwise, the expressions “around,” “approximately,” “substantially” and “in the order of” signify within 10% or 10°, and preferably within 5% or 5°.

The device is for example intended for the automotive industry. The autonomous driving trend generates an increasing demand for 3D telemetry sensors. Such sensors are for example SPAD LIDARs that are able to generate 3D images and videos. Such sensors for example comprise depth “Time Of Flight” imaging technology combined to standard 2D intensity imaging technology. Indeed, SPAD matrix technology is able to produce both.

The device can for example be used in the industrial field. Object recognition and manipulation by industrial robots, generates an increasing demand for 3D telemetry sensors, such as SPAD LIDARs.

The device is for example intended for being used in personal electronics. Face recognition and sophisticated autofocus cameras in smart phones and other consumer electronic devices increasingly demand for 3D telemetry sensors, such as SPAD LIDARs.

The device is for example intended for being used in communication equipment, or in computers and peripherals. For example, photonic detectors or optical communication devices integrate SPAD sensors for their high sensitivity, time correlated precision and the strong output signal due to avalanche carrier multiplication.

The disclosed device comprises a HEMT-type transistor. HEMT-type transistors are typically used in high-frequency and high-power applications such as satellite communications, radar systems, and microwave amplifiers. HEMT-type transistors may also be used in some specialized personal electronic devices such as high-end audio amplifiers or radio frequency (RF) transmitters. HEMT-type transistors are increasingly being used in car electrification, particularly in electric and hybrid vehicles. HEMT-type transistors are used in power electronics for controlling the flow of electrical energy in industrial equipment such as motors, generators, and transformers. HEMT-type transistors are used in LED (Light Emitting Diode) lighting systems for controlling the current and voltage. HEMT-type transistors help to improve the efficiency and performance of LED lighting systems. HEMT-type transistors are used in LED (Light Emitting Diode) lighting systems for controlling the current and voltage. HEMT-type transistors help to improve the efficiency and performance of LED lighting systems.

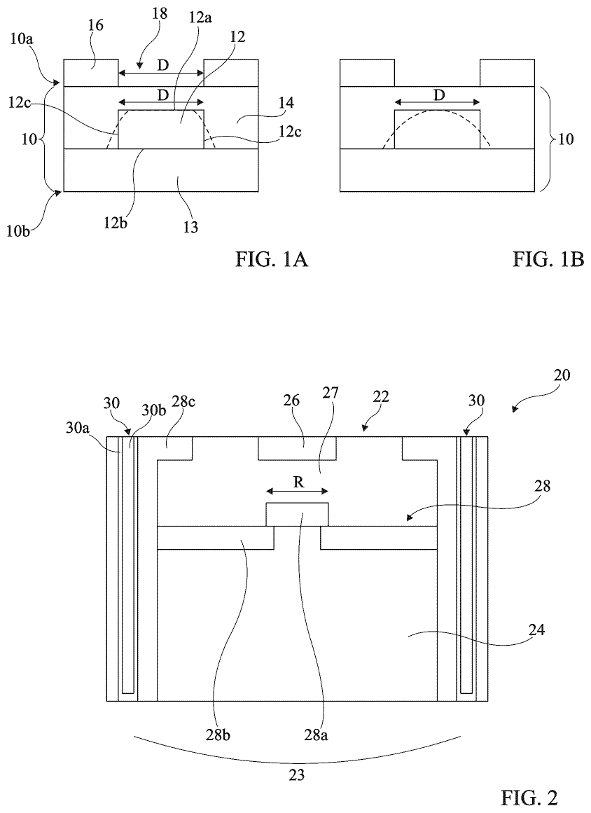

FIGS. 1A and 1B illustrate the definition of the lateral spatial resolution of a doping method. More especially, FIG. 1A is a view 1A of a case wherein a dimension D of a doped structure is above the lateral spatial resolution of the used doping method and a view 1B illustrates a case wherein the dimension D of a doped structure is below the lateral spatial resolution of the used doping method.

The views 1A and 1B illustrates a semiconductor substrate 10. The substrate 10 comprises an upper face 10a and a lower face 10b, opposed to the upper face 10a. It is wished to form a doped region 12 (in full line) in the substrate 10 with the doping method. The doping method is for example an ion implantation of dopant elements. The doping method is implemented from the side of the upper face 10a.

The region 12 has, in the views 1A and 1B, a rectangular shape. The region 12 therefore has, in the views 1A and 1B, an upper side 12a, in other words the side closest to the upper face 10a, a lower side 12b, in other words the side closest to the lower face 10b, and two lateral sides 12c, linking the upper and lower sides 12a,12b. The upper and lower side 12a,12b are parallel to each other. The upper side 12a is parallel to the upper face of the substrate 10a. The lateral sides 12c are perpendicular to the upper and lower sides of the region 12a,12b. In other words, the lateral sides 12c extend traverse to the upper and lower sides 12a,12b.

The region 12 is a rectangular parallelepiped. The views 1A and 1B correspond to a view of the region 12 parallel to a face of the rectangular parallelepiped.

The region 12 is a buried region. The region 12 is therefore surrounded on all sides by portion of the substrate 10. The region 12, and more especially the lower side of the region 12b, is, in the example of FIGS. 1A and 1B, separated from the lower face 10b by a region 13. The region 12, and more especially the upper side of the region 12a, is separated from the upper face 10a by a region 14. The region 12, and more especially the lateral sides of the region 12c, is separated from the lateral walls of the substrate by portions of the region 14. It is wished for the region 12 to be clearly distinct from region 14.

The region 13 is for example a doped region. The region 13 is for example doped of the same conductivity type as the wanted region 12. The region 14 is for example either not doped or doped of a conductivity type opposed to the conductivity type of the region 13. Neither the region 13 or the region 14 are doped by the doping step forming the region 12.

The region 13 is entirely located between the region 12 and the lower face 10b. Therefore, there is no portion of the region 13 between the lateral sides of region 12 and the lateral walls of the substrate 10. For example, the upper face of region 13 is parallel to, and in contact with, the lower side of region 12.

The dimension D corresponds to the length of the region 12 in the plan of the views of FIGS. 1A and 1B. The dimension D corresponds to the width of the portion of the upper face of the region 12 closest to the upper face of the substrate 10. The dimension D corresponds to the width of the rectangular parallelepiped forming the region 12. The dimension D corresponds to the smaller distance between two opposite lateral walls of the rectangular region 12.

The doping method may include the formation of a hard mask 16 comprising an opening 18. The opening 18 is then located in regard of the emplacement of region 12. The opening 18 has dimensions, in a plan parallel to the plan of the upper face of the substrate 10a, identical to the dimensions of the region 12. In the case of such a doping method, the dimension D corresponds to the dimension of the opening 18 corresponding to the dimension D of the region 12.

The dotted lines of FIGS. 1A and 1B correspond to the upper and lateral sides of the region 12 obtained by the doping method when trying to form the region 12 represented in full line.

The lateral spatial resolution of a doping method is the smallest dimension D allowing the formation of a region 12 with a plane upper side. In FIG. 1A, the dimension D is above the value of the resolution of the used doping method. In this embodiment, the buried region 12 has a substantially flat and upper surface opposite the upper surface of the substrate 10a. In FIG. 1B, the dimension D is below the value of the resolution of the used doping method. Therefore, the formed region 12 comprises a curved upper side, without any plane portion.

Alternatively, if the doping method is used to form a doped region 14, regions 12 and 13 being for example undoped, doped with a different conductivity type than region 14, or doped more weakly than is wished for region 14, the doping method for example comprises a first sequence of a photolithography and an implantation of dopants for the part of region 14 above region 12 and a second sequence of a photolithography and an implantation of dopants for the part of region 14 on the sides of region 12. In the first sequence the opening in the mask is as represented in FIGS. 1A and 1B. In the second sequence, the mask is located above region 12 and the openings are at the location of the mask in FIGS. 1A and 1B. In this case, the lateral spatial resolution of a doping method is defined as the smallest dimension D allowing the formation of a region 14 where the interface with the upper side 12a of region 12 is plane.

For example, the doping method is an ion implantation method, in which case the lateral spatial resolution is proportional to the depth of the implantation. The doping method can also be the dopant implantation by thermal annealing, in which case the lateral spatial resolution is enlarged due to dopant diffusion during the annealing.

FIG. 2 illustrates an embodiment of an electronical device 20 comprising a single photon avalanche diode (SPAD) 22. More especially, FIG. 2 illustrates the SPAD 22 as part of a pixel 23. The SPAD is for example part of a Time of Flight telemetry device comprised in the device 20.

FIG. 2 represents a substrate 24 of the device 20, on and in which SPAD 22 is formed. The substrate 24 is a semiconductor substrate, for example in silicon. For example, a quenching circuit associated with the SPAD 22 is formed in and on another substrate.

The device 20 for example comprises a plurality of pixels, or circuits, 23. For example the pixels 23 are disposed in the pattern of an array.

Each SPAD 22 comprises a cathode 26 and an anode 28. The anode 28 comprises a region 28a, a region 28b and a region 28c.

The cathode 26 is a n-doped semiconductor region. The cathode 26 for example crop out at the upper face of the substrate 24. In other words, the cathode 26 is recessed and the upper face of the cathode 26 is coplanar with the upper face of the substrate 24. The cathode 26 for example has a cylindrical form. For example, the cathode 26 has, in the top view, a circular form. In other words, the upper face of the cathode 26 has a circular form. Alternatively, cathode 26 has, in the top view, the form of a rectangle, preferably a square, with smoothed angles. The cathode 26 has preferably a doping concentration substantially constant.

Region 28a is a p-doped semiconductor region. Region 28a is for example buried in the substrate 24. Region 28a has a plane, for example substantially plane, upper face. Region 28a for example has a cylindrical form. For example, region 28a has, in a top view, a circular form. In other words, the upper face of the region 28a has a circular form. Alternatively, region 28a has, in the top view, the form of a rectangle, preferably a square, with smoothed angles. Region 28a is for example located under the cathode 26. In other words, at least part of region 28a is vertically aligned with a part of the cathode 26. In the example of FIG. 2, region 28a is separated from cathode 26 by a portion of the substrate 24. Preferably, the region 28a has smaller horizontal dimensions than the cathode 26. The region 28a is for example separated from the cathode 26 by a portion 27 of the substrate 24, not part of the cathode or the anode of the SPAD. Said portion is preferably N doped and has a doping concentration lower than the doping concentration of the region 28 a and of the cathode 26, preferably at least 100 times lower. Portions of the substrate are on lateral surfaces of the region 28a. The region 28a, the cathode 26 and the portion 27 of the substrate located between the region 28a and the cathode 26 a PIN of the SPAD.

Alternatively, the region 28a and the cathode 26 can be in contact. Therefore, the region 28a and the cathode 26 are not separated by a portion of the substrate 24. Preferably, the upper face of the region 28a is then entirely in contact with the cathode 26. In this case, the regions 28a and the cathode 26 form a PN junction of the SPAD.

Region 28b is a p-doped semiconductor region. Region 28b is for example buried in the substrate 24. Region 28b is preferably located under the region 28a. In other words, the region 28a is preferably located between region 28b and the cathode 26. Region 28b has for example the form of a ring. Region 28b laterally surrounds a portion of the substrate 24 vertically aligned with region 28a. Region 28b and region 28a are preferably in contact. Part of the upper face of region 28b is preferably in contact with the lower face of region 28a. Therefore, there is a vertical overlap between the regions 28a and 28b. The overlap ensures the electrical continuity of the anode.

Preferably, the overlap between region 28a and region 28b is lower than 0.5 μm, for example lower that 0.1 μm. The overlap is for example formed by the doping pattern blurring during the doping steps.

The existence of an overlap of these two regions 28 a and 28 b higher than 0.5 μm would cause the formation of a region around the interface between the regions 28a and 28b of increased p doping (compared to the regions 28a and 28b individually). This would make the SPAD more sensitive to potential barrier. To ensure that the potential barrier would not impede the efficiency of the SPAD, it would be required that the strength of the p doping be reduced. The doping gradient in the junction, which is the key driver of the electric field maximum, would be diminished.

Region 28c is a p-doped semiconductor region. Region 28c extends vertically in the substrate 24. Region 28c extends from the upper face of the substrate 24 to at least the level of the region 28b. Regions 28b and 28c are in contact, for example laterally. The upper face of the region 28c is for example coplanar with the upper face of the substrate 24. The width of the region 28c is for example higher at the level of the upper face of the substrate than at the level of the region 28b. For example, the region 28c comprises an upper part, having a first, preferably substantially constant, width, and a lower part having a second, preferably substantially constant, width. The second width is for example lower than the first width. Region 28c has, in a top view, the form of a ring. Region 28c surrounds the cathode 26, and the regions 28a and 28b. Region 28c is separated from the cathode 26 by a portion of the substrate 24. In other words, the region 28c has an upper portion that protrudes and extends from its main vertical portion towards the cathode 26. The region 28c has a surface of the protrusion that faces the cathode 26.

Each region 28a, 28b, 28c has preferably a doping concentration substantially constant. The dopant concentration of region 28a is for example higher than the dopant concentration in region 28b. The dopant concentration of region 28b is for example lower than the dopant concentration in region 28c.

Each SPAD is surrounded by an electrically insulating wall 30. Preferably, the walls 30 surrounding the different SPAD have the same dimensions.

Preferably, the wall 30 extends, vertically, on the entire height of the corresponding SPAD. Preferably, the wall 30 extends, vertically, at least from the point of the cathode 26 and anode 28 closest to the upper face of the substrate to the point of the cathode 26 and anode 28 the farthest to the upper face of the substrate. In other words, in the example of FIG. 2, the wall 30 extends, vertically, at least from the upper face of the cathode, corresponding to the upper face of the substrate and to the upper face of the region 28c, to the lower face of the region 28c, corresponding for example to the lower face of the substrate 24.

Each wall 30 surrounds laterally the corresponding SPAD. In other words, each SPAD is, preferably entirely, separated from the neighboring SPAD by a portion of the wall 30. In the example of FIG. 2, each SPAD is surrounded by a wall 30 associated to said SPAD and distinct from the walls 30 surrounding the other SPAD. Therefore, two neighboring SPAD are separated by portions of two different walls. In the example of FIG. 2, the different walls, surrounding the different SPAD, are not in contact. In other words, the different walls, surrounding the different SPAD, are separated from each other by portions of the substrate 24.

Preferably, the walls 30 are optically insulating. The walls 30 are for example of the back-side deep trench insulation (BDTI) type. The walls 30 for example comprises a sheath 30a in an electrically insulating material, for example silicon oxide or silicon nitride, and a core 30b in an optically insulating material, for example in metal. By optically insulating material, it is meant a material at least partially opaque, preferably entirely opaque, to the working wavelength of the SPAD, for example all wavelength of the visible range and/or all wavelength of the near infrared range. The walls 30 are for example configured to be polarized. More especially, the conductive core of the walls 30 are polarized, for example by a negative voltage, so that the semiconductor substrate 24 in the pixel is depleted, for example fully depleted.

The region 28a has a dimension R. The dimension R corresponds to the smallest horizontal dimension of the plane upper face of the region 28a. If the region 28a has, in top view, the shape of a disk, the dimension R corresponds to the diameter of the disk. If the region 28a has, in top view, the shape of a rectangle, the dimension R corresponds to the smallest dimension of the rectangle, in other words the width.

In order to maximize the breakdown probability of the SPAD, the dimension R is configured to be as small as possible in order to generate a single hot spot. In practice, the dimension R is configured to be smaller than, or equal to, 150% of the lateral spatial resolution of the doping method used to form the region 28a, preferably smaller than, or equal to, 130% of the lateral spatial resolution of the doping method used to form the region 28a. Preferably, the dimension R is lower than 1.2 μm, for example between 0.7 μm and 1.2 μm, for example lower than 1 μm. The dimension R is independent from the dimensions of the SPAD, therefore independent from the dimensions of the cathode 26. The dimension R is higher than the lateral spatial resolution of the doping method used to form the region 28a so that the desired doping profiles can be obtained.

In other words, the doped region 28a has lateral surfaces in the substrate 27. The dimension R is between the lateral surfaces of the doped region 28a along a first direction. The doped region 28a is on an undoped region of the substrate 24 so that the lateral surfaces of the doped region 28a extend past the undoped region of the substrate 24 along the first direction so that the lateral surfaces of the doped region 28a are on doped regions 28b. Said differently, the undoped region of the substrate 24 that is in contact with the doped region 28a extends along the first direction for a dimension that is less than the dimension R.

As the PN junction of the SPAD is located between the region 28a and the cathode 26, the smallest dimensions of the PN junction is for example smaller than, or equal to, 150% of the lateral spatial resolution of the doping method used to form the region 28a, preferably smaller than, or equal to, 130% of the lateral spatial resolution of the doping method used to form the region 28a.

The manufacturing method of the SPAD comprises:
a) the doping of the substrate 24;
b) the doping of the substrate in order to form the regions 28b;
c) the doping of the substrate in order to form the region 28a;
d) the doping of the substrate in order to form the region 28c;
e) the formation of the walls 30; and
f) the doping of the substrate in order to form the cathode 26.

For example, the step d) comprises the formation of a hard mask, not represented, on the upper face of the substrate, the hard mask comprising an opening above the localization of the region 28a. the doping step is implemented through the opening of the hard mask. The opening is preferably rectangular shaped, in top view. Preferably, at least one of the horizontal dimensions of the opening, for example length or width, is lower than smaller than, or equal to, 150% of the lateral spatial resolution of the doping method used to form the region 28a, preferably smaller than, or equal to, 130% of the lateral spatial resolution of the doping method used to form the region 28 a.

In previous implementations of SPAD, the SPAD were separated, and insulated, from each other by semiconductor junctions, for example PN junctions. In this kind of structure, it was considered necessary to ensure that the PN junction between the cathode and the anode was the largest possible in order to have a uniformity of electrical field in the SPAD and a maximum fill factor between the SPAD junction area and the total area. In current SPAD, manufacturers have continued to try and obtain SPAD with a large junction PN between the cathode and the anode. For example, it is common for current SPAD to have a dimension R corresponding to ⅘ of the width of the SPAD.

However, the inventors discovered that, in the presence of insulating walls such as the walls 30 of FIG. 2, as the junction size is reduced, it creates a funneling effect of electric field into the PN junction which is beneficial for the breakdown probability. The funneling effect collects and drives photogenerated electrons to a central small hot spot in the PN junction formed by the cathode and the anode.

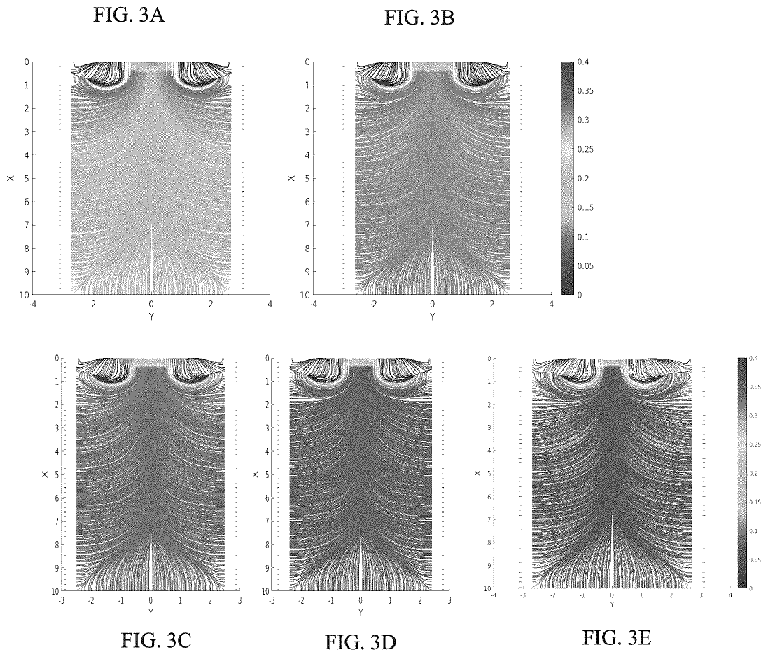

FIG. 3 illustrates example of breakdown probabilities in different single photon avalanche diodes. FIG. 3 comprises five views 3A, 3B, 3C, 3D, 3E illustrating the breakdown probabilities in SPAD such as the SPAD of FIG. 2 having different values of the dimension R. The dimension R is the only difference between the SPADs of the views 3A, 3B, 3C, 3D, 3E.

The dimension R of the SPAD of view 3A is higher than the dimension R of the SPAD of view 3B. The dimension R of the SPAD of view 3B is higher than the dimension R of the SPAD of view 3C. The dimension R of the SPAD of view 3C is higher than the dimension R of the SPAD of view 3D. The dimension R of the SPAD of view 3D is higher than the dimension R of the SPAD of view 3E. Furthermore, the values of the dimension R of the SPAD of views 3A to 3D are higher than the lateral spatial resolution of the doping method used to form the anode of the SPAD. The value of the dimension R of the SPAD of view 3E is the closest to the lateral spatial resolution of the doping method used to form the anode of the SPAD.

It is visible that, between the views 3A and 3D, the decrease of the value of the dimension R causes an increase of the breakdown probabilities in the entire SPAD. This effect is particularly visible if the value of the dimension R is below 150% of the lateral spatial resolution of the doping method used to form the anode, even more so if the value of the dimension R is below 130% of the lateral spatial resolution of the doping method used to form the anode. Furthermore, it is visible that in view 3E, where the dimension R is lower than the lateral spatial resolution, the breakdown probability ceases to improve, decrease around the region 28a. The inventors have determined that this decrease is due to doping pattern blurring.

An advantage of the described embodiment is that the breakdown probability of the SPAD is maximized. In other words, the SPAD is advantageously more likely to trigger an avalanche upon reception of a photon.

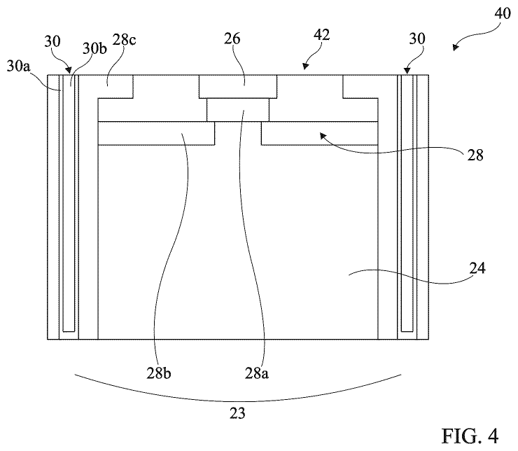

FIG. 4 illustrates another embodiment of an electronic device 40 comprising a single photon avalanche diode 42.

The device 40 comprises the elements of the device 20 of FIG. 2, as described in relation with FIG. 2. The device 40 comprises:
the pixel 23;
the substrate 24;
the cathode 26;
the anode 28, comprising the regions 28a, 28b and 28c; and
the wall 30, comprising the sheath 30a and the core 30b.

The device 40 differs from the device 20 in that the device 40 does not comprise the region 27 separating the cathode 26 and the region 28a. The cathode 26 and the region 28a are therefore in contact. The SPAD 42 therefore comprises a PN junction.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

An electronical device is summarized as including a single photon avalanche diode (22), the single photon avalanche diode (22) including a PN junction, the PN junction having a first dimension smaller than 1.2 μm, the single photon avalanche diode (22) being surrounded by an insulating wall (30), the first dimension being the smallest dimension of the junction.

A manufacturing method for an electronical device is summarized as including a single photon avalanche diode (22), the single photon avalanche diode (22) including a PN junction, the method including a doping step for manufacturing at least part of the anode of the single photon avalanche diode (22), the PN junction having a first dimension smaller than 1.2 μm, the single photon avalanche diode (22) being surrounded by an insulating wall (30), the first dimension being the smallest dimension of the junction.

The insulating wall (30) includes a conductive core (30b) and an insulating sheath (30a).

The cathode (26) of the single photon avalanche diode (22) includes a N doped region located in a substrate (24), the anode of the single photon avalanche diode (22) including: a first part (28a) located in regard to the cathode; and a second part (28b) surrounding a region of the substrate (24), said region of the substrate (24) being separated from the cathode by the first part (28a).

The PN junction is formed by the first part (28a) of the anode, the cathode (26) and the portion (27) of the substrate located between the first part (28a) of the anode and the cathode (26).

A second dimension is lower than 0.5 μm, the second dimension being the smallest dimension of the overlap between the first part (28a) and the second part (28b).

The first dimension is under 150%, for example under 130%, of the lateral spatial resolution of the doping method used to form at least part of the anode (28a) of the single photon avalanche diode (22).

The doping method used is ion implantation of dopant elements.

The first dimension is over 90% of the lateral spatial resolution of the doping method.

The lateral spatial resolution of a doping method is, when doping a region having the shape of a rectangular parallelepiped, the smallest value of the smallest dimension of the upper face of the region allowing the upper face of the region to be plane.

The first dimension is under 1 μm.

The first dimension is between 0.7 μm and 1.2 μm.

The device includes a time of flight device, the single photon avalanche diode (22) being part of the time of flight device.

The method includes the formation of a hard mask, the hard mask comprising an opening, at least one of the dimensions of the opening being smaller than 150% of the lateral spatial resolution of the doping method.

The doping is made from the face closest to the cathode.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An electronic device comprising:
a substrate;
a single photon avalanche diode having a PN junction, the PN junction including:
an anode having a first part;
a cathode opposite the first part of the anode along a first direction;
a portion of the substrate between the first part of the anode and the cathode; and
a first dimension of the first part of the anode along a second direction that is transverse to the first direction, the first dimension is less than 1.2 μm, and is the smallest dimension of the junction; and
an insulating wall surrounding the single photon avalanche diode.

2. The device according to claim 1, wherein the first dimension is less than 1 μm.

3. The device according to claim 1, wherein the insulating wall has a conductive core and an insulating sheath.

4. The device according to claim 1, wherein the cathode of the single photon avalanche diode includes an N-doped region located in the substrate, and wherein the anode of the single photon avalanche diode includes:
the first part aligned with the cathode; and
a second part surrounding a region of the substrate, the region of the substrate being separated from the cathode by the first part.

5. The device according to claim 1, wherein the first dimension is between 0.7 μm and 1.2 μm.

6. The device according to claim 3, wherein a second dimension is less than 0.5 μm, the second dimension being the smallest dimension of the overlap between the first part and the second part of the anode.

7. A manufacturing method, comprising:
forming a single photon avalanche diode having a PN junction, the PN junction including:
an anode having a first part;
a cathode opposite the first part of the anode along a first direction;
a portion of the substrate between the first part of the anode and the cathode; and
a first dimension of the first part of the anode along a second direction that is transverse to the first direction, the first dimension is less than 1.2 μm, and is the smallest dimension of the junction, wherein forming includes doping at least part of an anode of the single photo avalanche diode; and
forming an insulating wall surrounding the single photon avalanche diode.

8. The method according to claim 7, wherein the first dimension is under 150% of the lateral spatial resolution of the doping method used to form at least part of the anode of the single photon avalanche diode.

9. The method according to claim 7, wherein the doping method used is ion implantation of dopant elements.

10. The method according to claim 7, wherein the first dimension is over 90% of the lateral spatial resolution of the doping method.

11. The method according to claim 7, wherein the lateral spatial resolution of a doping method is, when doping a region having the shape of a rectangular parallelepiped, the smallest value of the smallest dimension of an upper face of the region allowing the upper face of the region to be plane.

12. The method according to claim 7, wherein the first dimension is between 0.7 μm and 1.2 μm.

13. The method according to claim 8, wherein forming the single photon avalanche diode includes the formation of a hard mask, the hard mask comprising an opening, at least one of the dimensions of the opening being smaller than 150% of the lateral spatial resolution of the doping method.

14. The method according to claim 8, wherein the doping is made from the face closest to the cathode.

15. The method according to claim 8, wherein the first dimension is under 130% of the lateral spatial resolution of the doping method used to form at least part of the anode of the single photon avalanche diode.

16. A device, comprising:
a substrate having a first surface opposite a second surface;
a first doped region buried in the substrate;
a second doped region buried in the substrate and opposite the first doped region along a first direction;
a third doped region on a first undoped region of the substrate; and
a fourth doped region in the substrate and opposite the third doped region along a second direction that is transverse to the first direction, a second undoped region of the substrate separating the third and fourth doped regions.

17. The device of claim 16, comprising a fifth doped region extending from the first surface of the substrate to the second surface of the substrate, the fifth doped region contacting the first doped region, and the fifth doped region having a portion adjacent to the first surface of the substrate extending along the first direction, the fourth doped region opposite the portion of the fifth doped region.

18. The device of claim 17, comprising an insulating layer on the fifth doped region.

19. The device of claim 16, wherein the fourth doped region is n-doped.

20. The device of claim 16, wherein the first, second, and third doped regions are p-doped.
